(19) United States
(12) Patent Application Publication
(10) Pub. No.: US 2024/0204137 A1
(43) Pub. Date: Jun. 20, 2024

(54) RADIATION-EMITTING SEMICONDUCTOR CHIP AND METHOD FOR MANUFACTURING A RADIATION-EMITTING SEMICONDUCTOR CHIP

(71) Applicant: ams-OSRAM International GmbH, Regensburg (DE)

(72) Inventors: Ali Mahdavi, München (DE); Ines Pietzonka, Donaustauf (DE); Stefan Barthel, Regensburg (DE); Alvaro Gomez-lglesias, Regensburg (DE)

(21) Appl. No.: 18/554,701

(22) PCT Filed: Apr. 5, 2022
(86) PCT No.: PCT/EP2022/059012

§ 371 Date: Oct. 10, 2023

(30) Foreign Application Priority Data
Apr. 20, 2021 (DE) 10 2021 109 960.9

(51) Int. Cl. H01L 33/24; H01L 25/075; H01L 33/62

(52) U.S. Cl. CPC H01L 33/24; H01L 25/0753; H01L 33/62

(57) ABSTRACT

In an embodiment a radiation-emitting semiconductor chip includes a first doped region, an active region adjacent to the first doped region and a second doped region arranged on a side of the active region facing away from the first doped region, wherein the first doped region is structured in a step-like manner and includes several planes in a direction perpendicular to a main extension plane of the semiconductor chip, and wherein the active region covers the first doped region on a side surface and a top surface.

### CROSS-REFERENCE TO RELATED APPLICATIONS

This patent application is a national phase filing under section 371 of PCT/EP2022/059012, filed Apr. 5, 2022, which claims the priority of German patent application 102021109960.9, filed Apr. 20, 2021, each of which is incorporated herein by reference in its entirety.

### TECHNICAL FIELD

A radiation-emitting semiconductor chip and a method for manufacturing a radiation-emitting semiconductor chip are provided.

### SUMMARY

Embodiments provide a radiation-emitting semiconductor chip that can be operated particularly efficiently. Further embodiments provide a method for manufacturing such a radiation-emitting semiconductor chip.

The radiation-emitting semiconductor chip is, for example, a light-emitting diode chip that, during operation, emits infrared light, colored light, or white light of any color temperature.

According to at least one embodiment of the radiation-emitting semiconductor chip, the radiation-emitting semiconductor chip comprises a first doped region. The first doped region is formed with a doped semiconductor material. For example, the semiconductor material of the first doped region and the semiconductor material of the subsequent regions are each a III-V compound semiconductor material. Overall, the radiation-emitting semiconductor chip can then be a semiconductor chip, which is based on a III-V compound semiconductor material.

A III-V compound semiconductor material comprises at least one element from the third main group, such as B, Al, Ga, In, for example, and one element from the fifth main group, such as N, P, As, for example. In particular, the term “III-V compound semiconductor material” comprises the group of binary, ternary or quaternary compounds, which contain at least one element from the third main group and at least one element from the fifth main group, for example nitride and phosphide compound semiconductors. Such a binary, ternary or quaternary compound can further comprise, for example, one or more dopants as well as additional constituents.

For example, the semiconductor chip is based on the material system InGaAlP or the material system InGaAlAs or the material system InGaAlN.

The first doped region can be, for example, a p-doped region or an n-doped region.

According to at least one embodiment of the radiation-emitting semiconductor chip, the semiconductor chip comprises an active region, which is intended to generate electromagnetic radiation and which is adjacent to the first doped region. In the active region of the radiation-emitting semiconductor chip the electromagnetic radiation is generated, which is emitted during operation of the radiation-emitting semiconductor chip.

For this, the active region comprises, for example, a multiple quantum well structure, a single quantum well structure or a heterostructure, such as a double heterostructure or a p-n junction, for example. The term quantum well structure does not have any meaning with regard to the dimensionality of the quantization. It thus comprises, among others, quantum wells, quantum wires and quantum dots and any combination of these structures.

For example, the active region is directly adjacent to the first doped region.

According to at least one embodiment of the radiation-emitting semiconductor chip, the radiation-emitting semiconductor chip comprises a second doped region, which is arranged at a side of the active region facing away from the first doped region. The second doped region is unequally doped with respect to the first doped region. This means, if the first doped region is p-doped, for example, the second doped region is n-doped. If the first doped region is n-doped, for example, the second doped region is p-doped.

According to at least one embodiment of the radiation-emitting semiconductor chip, the first doped region is structured. This means in particular that the first doped region is changed in its shape during the manufacturing of the radiation-emitting semiconductor chip by a structuring process. The first doped region is then in particular not a planar layer, which extends mainly in two spatial dimensions within the manufacturing tolerance, but the first doped region can be a three-dimensional structure. The first doped region then comprises in particular a non-planar, for example curved, outer surface.

In a sectional plane perpendicular to a main extension plane of the semiconductor chip, the first doped region can, for example, comprise the shape of a trapezoid. The three-dimensional shape of the first doped region can then correspondingly be a prism within the manufacturing tolerance. It is further possible, that the three-dimensional shape of the first doped region resembles or corresponds to a step pyramid, a hemisphere or a hemi-cylinder.

According to at least one embodiment of the radiation-emitting semiconductor chip, the active region covers the first doped region at a side surface and at a top surface. This means, the active region is not only arranged as a layer, which extends mainly in two spatial dimensions on a top surface of the first doped region, but the active region follows the first doped region conformally at least in places, so that the first doped region is also covered by the material of the active region on a side surface.

Thereby, it is possible, that the active region extends continuously from a side surface of the first doped region to a top surface of the first doped region. Furthermore, it is possible that the active region is not formed continuously and covers the first doped region only in places on a side surface and on the top surface.

The top surface of the first doped region is, for example, an outer surface of the first doped region, which is parallel to a main extension plane of the optoelectronic semiconductor chip. For example, the top surface is parallel within the fabrication tolerance to a main extension plane of a substrate on which the radiation-emitting semiconductor chip is fabricated.

A side surface of the first doped region thereby extends transversely to a main extension plane of the radiation-emitting semiconductor chip. The first doped region can thereby comprise two or more such side surfaces. The side surfaces can connect the top surface of the first doped region to a bottom surface of the first doped region facing away from the top surface. The bottom surface of the first doped region is in direct contact with, for example, a substrate, on which the first doped region is grown or a carrier, on which the first doped region is deposited.

According to at least one embodiment of the radiation-emitting semiconductor chip, the semiconductor chip comprises a first doped region, an active region, which is intended to generate electromagnetic radiation and which is adjacent to the first doped region, and a second doped region, which is arranged on a side of the active region facing away from the first doped region. Thereby, the first doped region is structured and the active region covers the first doped region on a side surface and on a top surface.

A radiation-emitting semiconductor chip described herein is based on the following considerations, among others: the efficiency of radiation-emitting semiconductor chips is often negatively affected by low radiation outcoupling efficiency and due to non-radiative recombination.

The low radiation outcoupling efficiency can be due to total internal reflection, which can occur in particular in radiation-emitting semiconductor chips with a planar light-emitting surface. This can then also lead to the fact that electromagnetic radiation generated in the radiation-emitting semiconductor chip can only emerge from the semiconductor chip in narrow angular ranges.

The radiation-emitting semiconductor chip described herein is now based, among others, on the idea of arranging the active region downstream of a first doped region, which is structured, so that the active region is also arranged on a side surface besides a top surface of the first doped region. In this way, a particularly large amount of electromagnetic radiation is generated, whose main radiation direction is perpendicular or nearly perpendicular to a radiation outcoupling surface of the radiation-emitting semiconductor chip, whereby the probability of total reflection occurring in the radiation-emitting semiconductor chip is reduced.

Furthermore, this increases the angular range in which electromagnetic radiation is emitted by the semiconductor chip. Ideally, the active region is curved in its course and, for example, circular in places in a sectional plane perpendicular to a main extension plane of the optoelectronic semiconductor chip. The same then preferably also applies to the radiation outcoupling surface of the semiconductor chip.

According to at least one embodiment of the radiation-emitting semiconductor chip, the active region completely covers the side surface of the first doped region.

In this case, the side surface of the first doped region can, for example, be planar within the manufacturing tolerance and the active region is applied to this planar side surface of the first doped region. The active region can then extend continuously from the first side surface to the top surface of the first doped region, for example. For example, it is thereby possible, that the first doped region comprises at least two, for example, or four such side surfaces.

According to at least one embodiment of the radiation-emitting semiconductor chip, the semiconductor chip comprises a main extension plane and the active region extends obliquely to the main extension plane in places. For example, the main extension plane of the semiconductor chip extends in parallel to the top surface of a substrate on which the semiconductor chip is formed.

The main extension plane extends, for example, oblique or perpendicular to a growth direction, with which the regions of the radiation-emitting semiconductor chip are epitaxially grown.

The active region can thereby be arranged in places oblique to the main extension plane and in places parallel to the main extension plane of the semiconductor chip on the first doped region. For example, where the active region is applied to a side surface of the first doped region, it extends oblique to the main extension plane, and where it is applied to a top surface of the first doped region, it extends in parallel to the main extension plane.

According to at least one embodiment of the radiation-emitting semiconductor chip, the active region is curved. This means, in this embodiment, the active region can comprise at least approximately a curvature and, for example, follow the course of a spherical surface in places. This is the case if the first doped region comprises a correspondingly structured outer surface.

For example, the active region can curve in places in the direction of the substrate. The active region can be in direct contact with the substrate. For example, the active region is in direct contact with the substrate only in places. In particular, the active region can be in direct contact with an electrically insulated region of the substrate.

According to at least one embodiment of the radiation-emitting semiconductor chip, the first doped region is structured in a step-like manner and comprises multiple planes in a direction perpendicular to a main extension plane of the semiconductor chip. That is, the first doped region can approximate the shape of a step pyramid, for example. The active region can then be located both on the side surfaces of the first doped region that extend transversely or perpendicularly to the main extension plane of the semiconductor chip and the surfaces of the first doped region that extend parallel to the main extension plane of the semiconductor chip.

According to at least one embodiment of the radiation-emitting semiconductor chip, the first doped region tapers in a direction perpendicular to a main extension plane of the semiconductor chip. That is, in a direction perpendicular to the main extension plane, the area of a cross-sectional area, that extends in parallel to the main extension plane, of the first doped region decreases.

According to at least one embodiment of the radiation-emitting semiconductor chip, the radiation emitting semiconductor chip comprises a first contact, which is electrically conductively connected to the first doped region, wherein the first contact extends into the first conductive region.

The first contact can, for example, be formed with an electrically conductive material, in particular a metallic material or transparent conductive oxides. The first contact can in particular in the area of a geometric centre of the first doped region, extend into the same. The first contact can thereby also be formed in such a way that it tapers in a direction perpendicular to a main extension plane of the semiconductor chip. With such a first contact, it is possible to contact the radiation-emitting semiconductor chip particularly uniformly.

According to at least one embodiment of the radiation-emitting semiconductor chip, the semiconductor chip is a micro light-emitting diode chip. The radiation-emitting semiconductor chip then comprises an edge length of less than or equal to 20 μm. The edge length is then, for example, the edge of the radiation-emitting semiconductor chip with the smallest lateral extent. In another direction, the radiation-emitting semiconductor chip can then comprise an edge length that is greater than 20 μm.

According to at least one embodiment of the radiation-emitting semiconductor chip, the semiconductor chip comprises a non-planar, in particular curved, radiation outcoupling surface, through which the radiation generated during operation can leave the semiconductor chip. The radiation outcoupling surface can be formed by an outer surface of the semiconductor chip.

The semiconductor chip then preferably also comprises a non-planar, in particular curved, active region. The active region can comprise an outer surface facing the radiation outcoupling surface, which extends similarly or parallel to the radiation outcoupling surface.

If the radiation outcoupling surface and the active region are non-planar, the electromagnetic radiation of the semiconductor chip can preferably be emitted at any point of the active region in a wide angular range.

Furthermore, a method for manufacturing a radiation-emitting semiconductor chip is provided. In particular, the method can be used to manufacture a radiation-emitting semiconductor chip described herein. This means, all features disclosed for the radiation-emitting semiconductor chip are also disclosed for the method, and vice versa.

In the method, first a substrate is provided. The substrate may be, for example, a grow-on substrate, which may be formed with, for example, sapphire, SiC, GaAs, Si, InP and the like, depending on the material of the semiconductor chip that is deposited on the substrate. The substrate comprises a main extension plane that, for example, extends in parallel to a top surface of the substrate on which the subsequent layers are deposited. The substrate may further be, herein and hereinafter, a grow-on substrate and/or epitaxially grown layers grown on a grow-on substrate. The grow-on substrate can then also be removed.

The substrate can be formed electrically insulating at least in places. In other words, the substrate comprises electrically non-conductive regions at least in places. For example, the substrate is formed electrically insulating.

According to at least one embodiment of the method, the method comprises a method step in which a first doped region is deposited. The deposition of the first doped region is performed, for example, epitaxially. Thereby, it is possible that the first doped region is deposited directly onto the substrate or that buffer layers are located between the substrate and the first doped region. The first doped region is, for example, formed with an n-doped or a p-doped semiconductor material.

According to at least one embodiment, the method comprises a step, wherein a patterning of the first doped region takes place such that the first doped region tapers in a direction away from the substrate.

In this context, the structuring of the first doped region can take place, for example, by material removal, such as etching, for example. Moreover, it is possible that the first doped region is grown using masks. Thereby, it is possible that for structuring the first doped region subsequently masks are used, comprising mask openings that are different from one another, in which the material of the first active region is deposited. For example, the size of the mask opening can then be successively reduced during the growth of the first active region, whereby a tapering of the first doped region in a direction away from the substrate is achieved as well.

According to at least one embodiment of the method, a deposition of an active region is performed such that the active region covers a side surface of the first doped region. The active region is then located, in particular, in direct contact with a side surface of the first doped region in the finished semiconductor chip.

According to at least one embodiment, the method comprises a method step, wherein the deposition of a second doped region on the active region takes place. The second doped region is doped unlike the first doped region. The active region and the second doped region can be in direct contact with each other. The deposition of the active region is in particular also performed epitaxially and can be performed in the same epitaxy unit as the deposition of the first doped region.

The deposition of the second doped region is also performed epitaxially and can be performed in the same epitaxy unit as the deposition of the active region.

According to at least one embodiment of the method, the method comprises the following method steps:
providing a substrate,
depositing a first doped region,
structuring of the first doped region such that the first doped region tapers in a direction away from the substrate,
depositing of an active region, such that the active region covers a side surface of the first doped region,
depositing of a second doped region on the active region.

Thereby, in particular, it is possible that the method steps are performed in a sequence other than that specified. For example, the deposition of the active region can be performed prior to the deposition of one of the doped regions.

According to at least one embodiment of the method, the structuring of the first region takes place multiple times so that the first region is structured in a step-like manner and has several levels along the direction away from the substrate. The structuring can be performed, for example, by etching the first region accordingly or by structuring during the growth of the first region by means of masks.

According to at least one embodiment of the method, a portion of the active region is deposited prior to the initial deposition of the first doped region and the second doped region. In other words, in this embodiment of the method, a deposition of at least a portion of the active region takes place before any of the doped regions is generated.

According to at least one embodiment of the method, the active region is removed in places before a deposition of the first doped region and the second doped region is performed. For example, the active region is deposited over a large area on the substrate. Subsequently, the active region is removed in places and material of the first doped region and/or of the second doped region is deposited in the openings of the active region produced in this way.

In the following, the optoelectronic semiconductor chip described herein as well as the method described herein are explained in more detail with reference to figures and the associated exemplary embodiments.

### BRIEF DESCRIPTION OF THE DRAWINGS

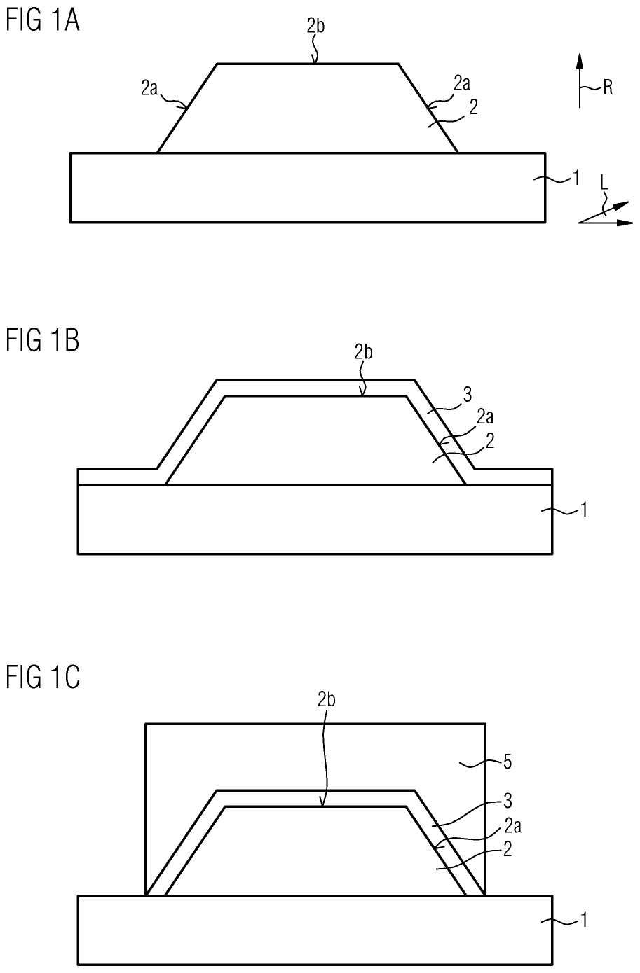

With reference to the schematic sectional views of FIGS. 1A to 1D, a first exemplary embodiment of a method described herein is explained in more detail.

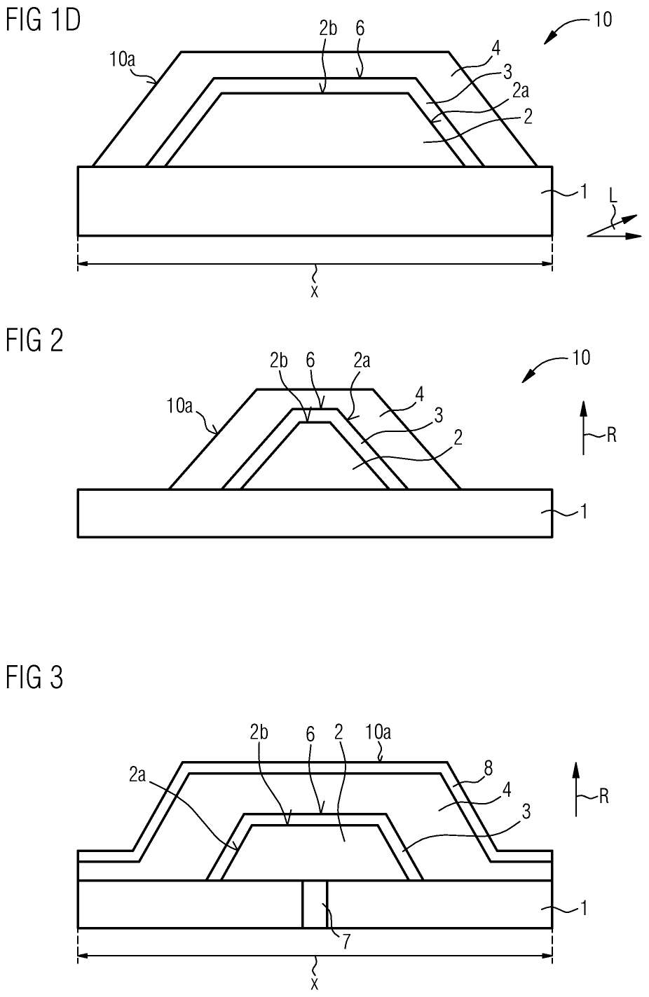

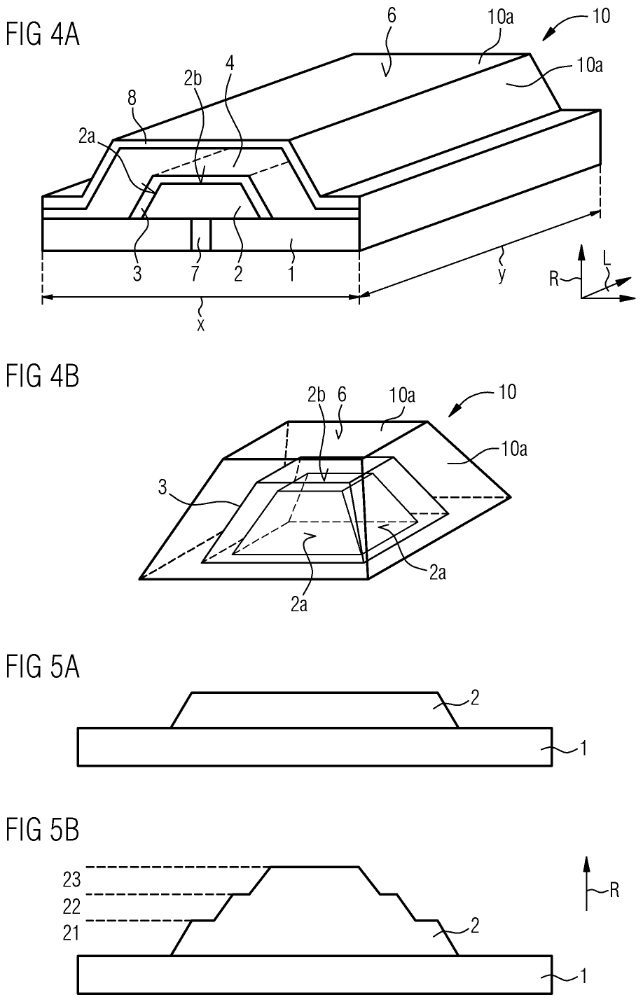

With reference to the schematic sectional views of FIGS. 2 and 3, exemplary embodiments of a radiation-emitting semiconductor chip described herein are explained in more detail.

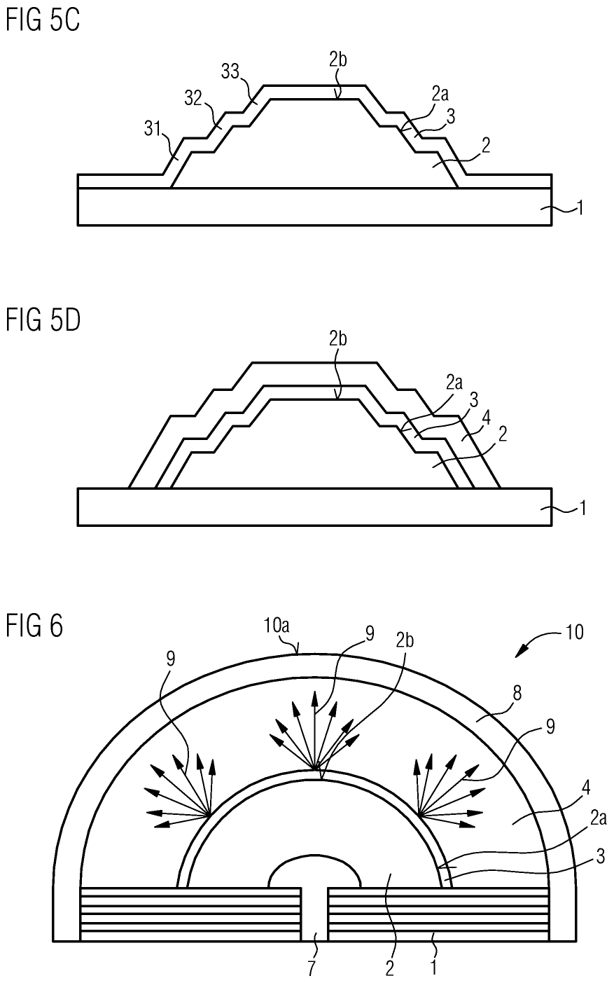

With reference to the perspective schematic views of FIGS. 4A and 4B, a further exemplary embodiment of a radiation-emitting semiconductor chip described herein is explained in more detail.

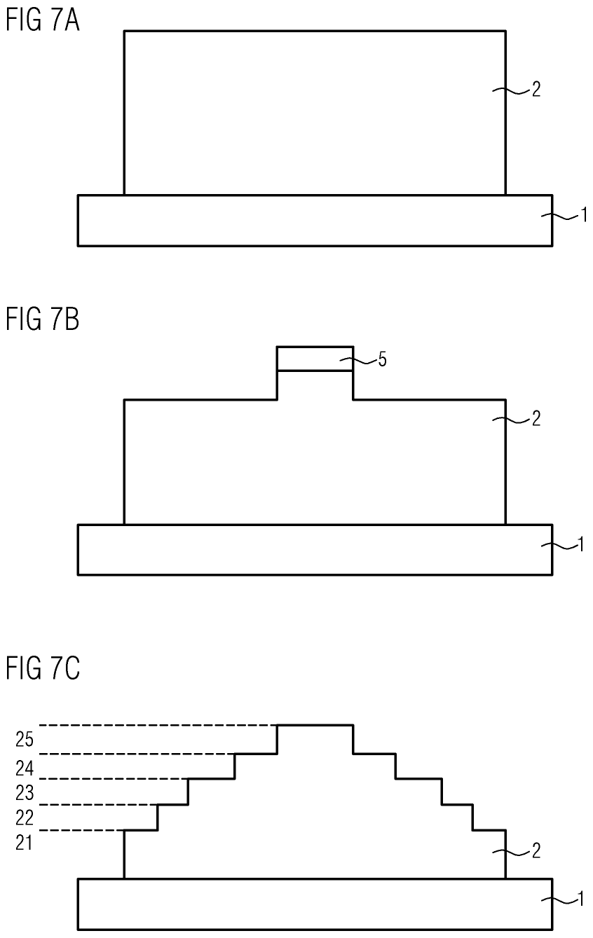

With reference to the schematic views of FIGS. 5A to 5D, a further exemplary embodiment of a method described herein is explained in more detail.

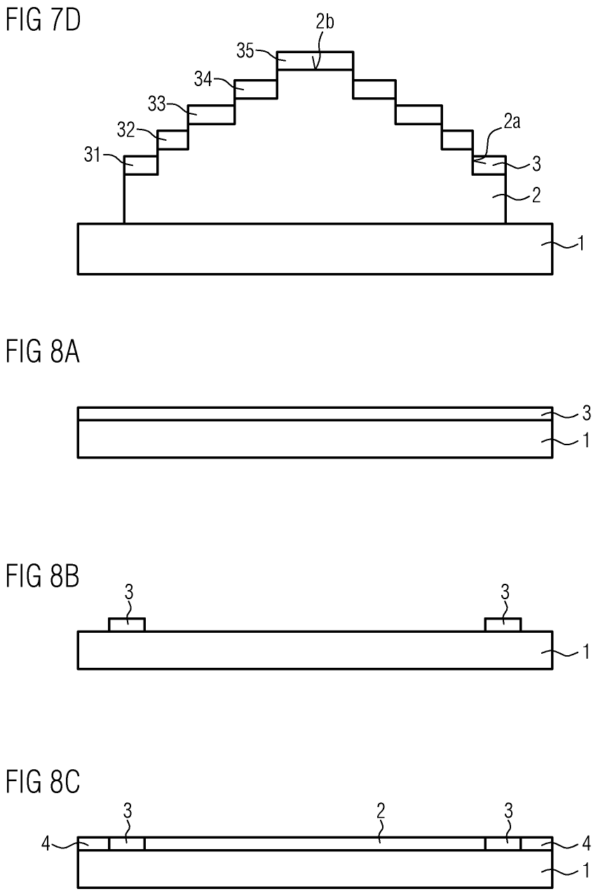

With reference to the schematic sectional view of FIG. 6, a further exemplary embodiment of a radiation-emitting semiconductor chip described herein is explained in more detail.

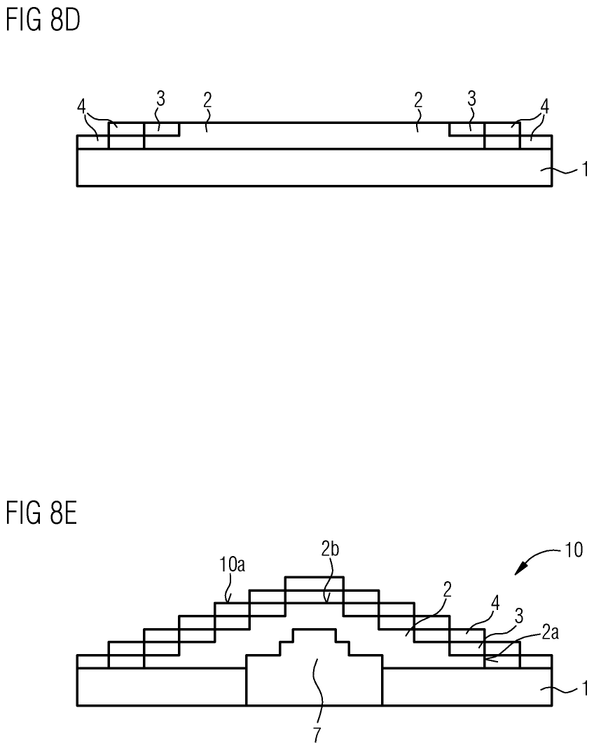

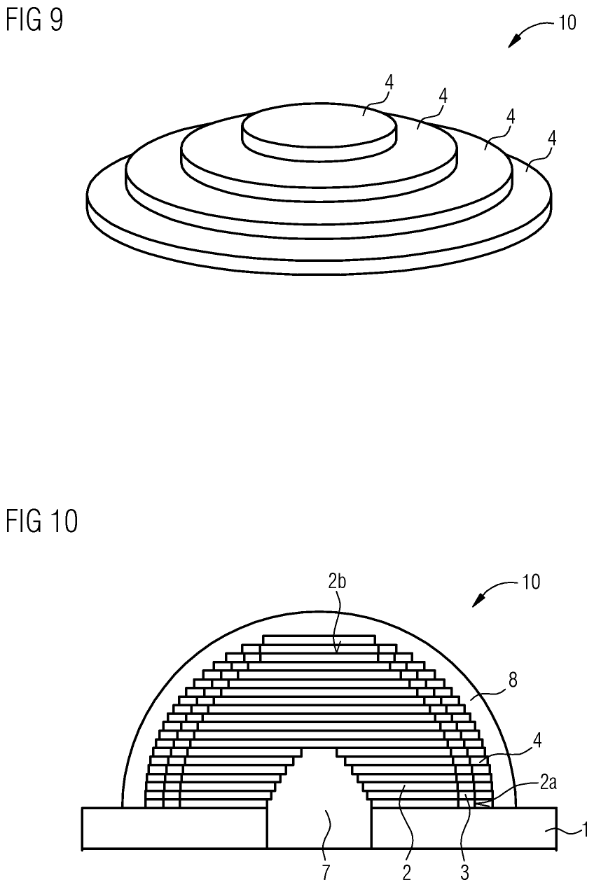

With reference to the schematic sectional views of FIGS. 7A to 7D as well as FIGS. 8A to 8E, further exemplary embodiments of a method described herein are explained in more detail.

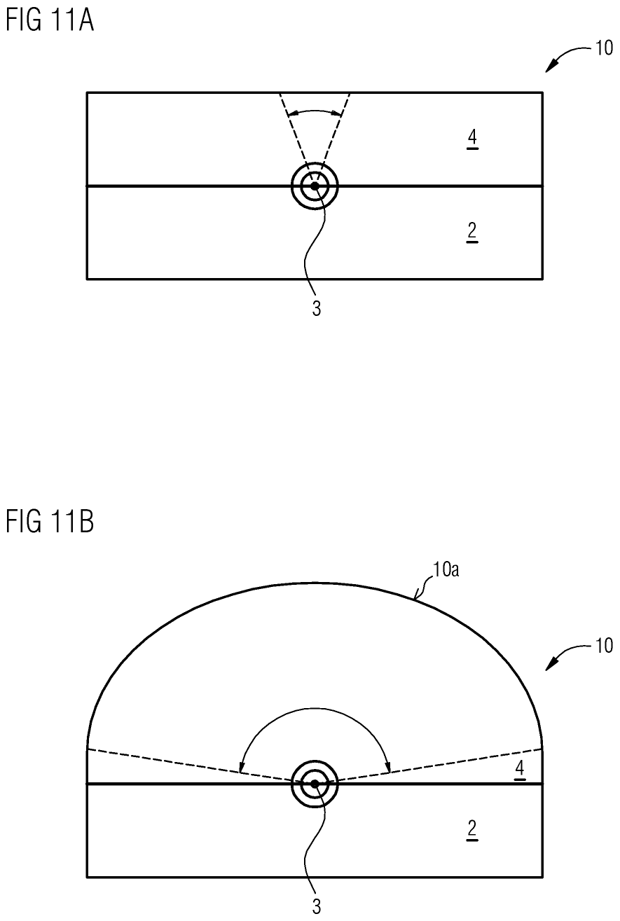

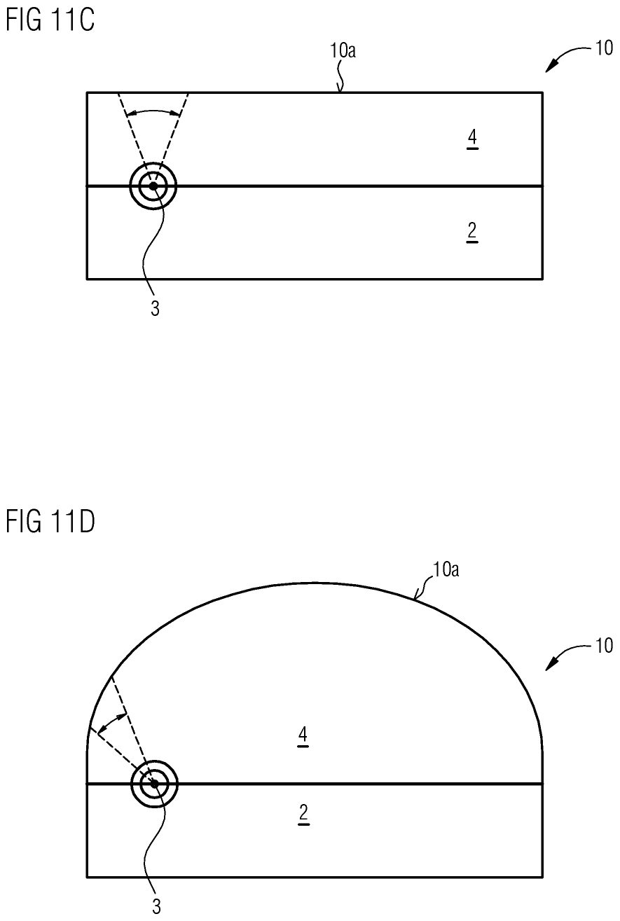

With reference to the schematic views of FIGS. 9 and 10, further exemplary embodiments of radiation-emitting semiconductor chips described herein are explained in more detail.

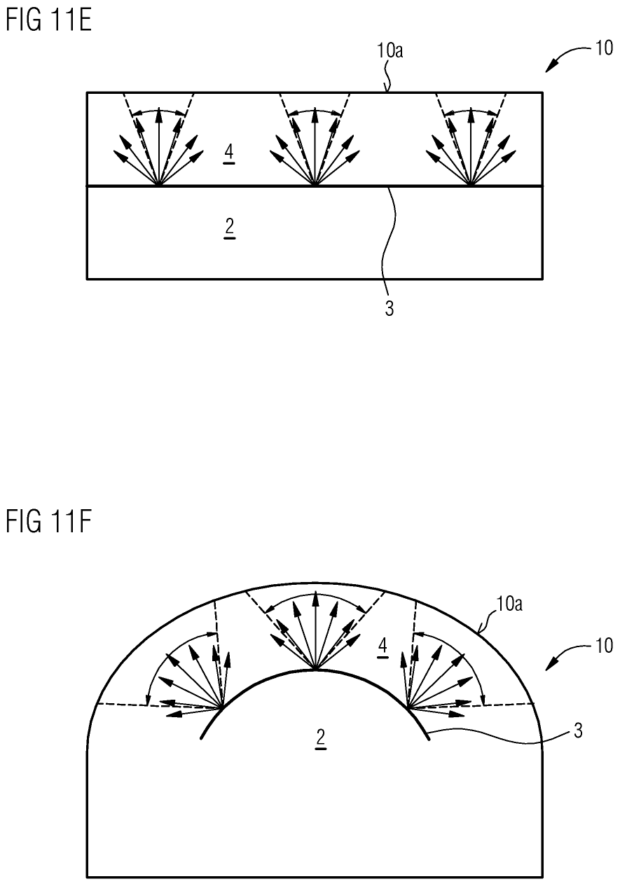

With reference to the schematic views of FIGS. 11A to 11F, the operation of a radiation-emitting semiconductor chip described herein is explained in more detail.

Elements that are identical, similar or have the same effect are given the same reference signs in the figures. The figures and the proportions of the elements shown in the figures are not to be regarded as to scale. Rather, individual elements may be shown exaggeratedly large for better representability and/or for better comprehensibility.

### DETAILED DESCRIPTION OF ILLUSTRATIVE EMBODIMENTS

In connection with the schematic sectional views of FIGS. 1A to 1D, a first exemplary embodiment of a method described herein is explained in more detail. In the method, a substrate 1 is provided.

On the substrate 1 a first doped region 2 is deposited. The first doped region 2 is, for example, a region formed with a p-doped semiconductor material.

Subsequently, a structuring of the first doped region 2 takes place so that it is formed trapezoidal in a cross-section perpendicular to a main extension plane L of the semiconductor chip 10, as shown schematically in FIG. 1A. The first region 2 structured in this way tapers in a direction R away from the substrate 1.

The first doped region 2 then comprises side surfaces 2a that run transversely to the main extension plane L. Furthermore, the first doped region 2 comprises a top surface 2b that runs in parallel to the main extension plane L.

After the first doped region 2 is structured and prepared for an overgrowth, an overgrowth takes place by deposition of an active region 3, such that the active region covers a side surface 2a of the first doped region 2.

In the present case, the active region 3 completely and conformally covers the side surfaces 2a as well as the top surface 2b of the first doped region 2. This is shown in FIG. 1B.

For overgrowth with the active region, the side surfaces 2a of the first doped region are preferably group V-terminated. In this way, the active region can be grown with particularly good crystal quality on the top surface 2b, which runs parallel to the (001)-crystal plane, for example, and in side surfaces 2a.

In a next method step, FIG. 1C, the lateral regions of the active region 3 are removed, such that only regions of the active region 3 remain, which are located on a side surface 2a and the top surface 2b of the first doped region 2.

For this, a corresponding mask 5 can be applied. The mask 5 can be formed with SiNx, SiON or SiO2, for example, and applied by means of an ALD method, for example. The removal of the active region 3 in the region not covered by the mask 5 takes place, for example, by means of dry- or wet-chemical etching.

In the next method step, FIG. 1D, the deposition of a second doped region 4 on the active region 3 is performed. The second doped region 4 is formed, for example, by an n-doped semiconductor material.

This results in a radiation-emitting semiconductor chip 10 as schematically shown in FIG. 1D, wherein the first region 2 is structured and the active region covers the first doped region 2 at the side surfaces 2a and a top surface 2b.

The radiation-emitting semiconductor chip 10 can thereby, as shown in FIG. 1D, comprise a first doped region with exactly one top surface 2b, which runs parallel to the main extension plane L of the semiconductor chip 10. Thereby, the structure size of the structuring of the first doped region 2 corresponds approximately to the edge length x of the radiation-emitting semiconductor chip 10. In other words, the first doped region 2 comprises, at its bottom surface 2c facing away from the top surface 2b, a lateral extension which corresponds to at least 20%, in particular at least 50% or at least 80% of the edge length x of the semiconductor chip 10.

The schematic sectional view of FIG. 2 shows a further exemplary embodiment of a radiation-emitting semiconductor chip 10 described herein. In this exemplary embodiment, compared to the exemplary embodiment of FIG. 1D, the size of the top surface 2b of the first doped region 2 is reduced. In this way, the shape of the active region 3 corresponds more to the shape of a semicircle than is the case, for example, for the exemplary embodiment of FIG. 1D. The probability of a total reflection when leaving the radiation-emitting semiconductor chip 10 is thus further reduced and the efficiency of the semiconductor chip 10 is increased, but the area of the active region 3 is reduced compared to the exemplary embodiment of FIG. 1D.

The schematic sectional view of FIG. 3 shows a further exemplary embodiment of a radiation-emitting semiconductor chip 10 described herein. In contrast to the exemplary embodiment of FIGS. 2 and 1D, in the exemplary embodiment of FIG. 3, the contacts 7 and 8 for external contacting of the radiation-emitting semiconductor chip 10 are now added. Thereby, the first contact 7 extends at least through the substrate 1 and/or an epitaxially grown layer. The second contact 8 is applied on the second doped region 4, for example, as a radiation-transmissive contact. The second contact 8 can be, for example, a contact which is formed with a TCO-material such as ITO, for example. The outer surface of the second contact 8 forms the radiation outcoupling surface 10a of the semiconductor chip 10.

The schematic perspective views of FIGS. 4A and 4B show further exemplary embodiments of a radiation-emitting semiconductor chip 10 described herein. In these exemplary embodiments, the semiconductor chip 10 extends longer in one spatial direction than in the other spatial direction. That is, the semiconductor chip 10 comprises an edge length x and a further edge length y, wherein the further edge length y is large relative to the edge length x.

The radiation-emitting semiconductor chip 10 thus has a strip-shaped extension and the area of the portions of the active region 3, which are applied on side surfaces 2a of the first doped region 2, is particularly large compared to the area of the top surface 2b.

Thus, on the one hand, the probability of a total reflection when electromagnetic radiation exits the semiconductor chip 10 is reduced, and on the other hand, the probability of non-radiative recombination at the surface is also reduced.

If the semiconductor chip 10 is formed in the InGaAlP material system, for example, the oblique regions of the active region 3 are oriented parallel to the (111) x-facet, wherein x=A and B can be. For other material systems, other facets can be advantageous.

As shown in FIG. 4B, the semiconductor chip 10 can be bounded in both lateral directions by side surfaces 2a. Such a 3D-geometry leads to an even stronger suppression of non-radiative recombination. The size of the semiconductor chip 10 is tunable, the emission perpendicular to the outcoupling surface 10a is maximized, the area for breaking up of total reflection is maximized, resulting in increased efficiency. Substrate and contacts are not shown in FIG. 4B.

Overall, a radiation-emitting semiconductor chip 10 described herein is characterized by improved radiation outcoupling efficiency because a particularly large amount of electromagnetic radiation is incident perpendicular to the radiation outcoupling surface 10a and the probability of non-radiative recombination is also reduced.

In connection with the schematic views of FIGS. 5A to 5D, a further exemplary embodiment of a method described herein is explained in more detail. In this exemplary embodiment, the first doped region 2 is structured in a step-like manner by multiple overgrowth, as shown in FIGS. 5A and 5B, so that the first doped region 2 comprises a plurality of planes 21, 22, 23 in the direction R, which is, for example, perpendicular to the main extension plane L.

In the next method step, FIG. 5C, the active region 3 is then conformally deposited so that it comprises corresponding sections 31, 32, 33 along the planes 21, 22, 23 which are oblique to the main extension plane L.

The second doped layer 4 is correspondingly conformally deposited over the active region 3, FIG. 5D.

Thus, an embodiment of the radiation-emitting semiconductor chip 10 can be realized as shown in idealized form in FIG. 6. There, the first doped region 2 is hemispherical structured and the active region 3 is correspondingly conformally applied to the first doped region 2. Electromagnetic radiation 9 generated in the active region 3 then strikes the outer surface of the semiconductor chip 10 largely perpendicularly and can be emitted without significant total reflection. This results in a theoretical radiation outcoupling efficiency of 69.6% compared to a radiation outcoupling efficiency of only about 14% for a planar active region. Thereby, it is assumed that the semiconductor material of the second doped region comprises a refractive index of 3 and that the substrate 1 is formed to be reflective, for example as a Bragg reflector. Further, the radiation outcoupling surface 10a is curved conformally to the outer surface of the active region 3, which faces the radiation outcoupling surface 10a.

In connection with the schematic sectional views of FIGS. 7A to 7D, a further exemplary embodiment of a method described herein is explained in more detail.

In this exemplary embodiment, the first doped region 2 is subsequently etched using different masks 5 so that also a step-like or step-shaped profile results with planes 21 to 25 of the first doped region 2. In this way, different geometries are possible for the first doped region 2 depending on the mask used, for example the shape of a step pyramid or an approximated hemisphere.

The etching steps are shown in connection with FIGS. 7B and 7C.

In FIG. 7D, it is shown that in each plane sections 31 to 35 of the active region 3 are arranged, which each extend to the side surface 2a in each plane of the first doped region 2. Subsequently, a second doped region 4 can be applied correspondingly (not shown).

In connection with the schematic views of FIGS. 8A to 8E, a further exemplary embodiment of a method described herein is explained in more detail. In this exemplary embodiment, as in the exemplary embodiment of FIGS. 7A to 7D, the active layer 3 is grown only in the (001)-plane, by which a technically particularly simple growth process is possible.

First, the active region 3 is deposited over a large area on the substrate 1, FIG. 8A.

Subsequently, a part of the active region 3 is removed by etching, such that only a ring on the substrate 1 remains, which is formed with material of the active region 3.

Onto the exposed regions of the substrate 1, the first doped region 2 inside the ring and the second doped region 4 outside the ring are subsequently deposited. This is shown in FIG. 8C.

This method is repeated for progressively smaller diameters of ring-shaped active regions 3, FIG. 8D.

The doped regions 2, 4 as well as the active regions 3 can be deposited via a MOCVD-process, wherein growth masks formed with silicon dioxide or silicon nitride come into use.

Subsequently, a first contact 7 is generated either through the substrate 1, FIG. 8 E, or the substrate 1 is detached and the first contact 7 is generated (not shown).

Optoelectronic semiconductor chips 10 as schematically shown in FIGS. 9 and 10 result, wherein a hemispherical design of the outer surface of the active region 3 can be achieved by as many epitaxial steps as possible. In the center of the first doped region 2, the first contact 7 extends into the first doped region 2.

In connection with the schematic views of FIGS. 11A to 11F, the operation of radiation-emitting semiconductor chips 10 described herein is explained in more detail.

FIG. 11A shows a radiation-emitting semiconductor chip 10 with a flat radiation outcoupling surface 10a. High refractive indices of the semiconductor material of the radiation-emitting semiconductor chip 10 result in a small extraction cone of the emitted radiation, as shown in FIG. 11A. A small extraction cone hinders emission from the active region 3.

FIG. 11B shows that by introducing a curved radiation outcoupling surface 10a such as would result for a semiconductor chip 10 described herein, the extraction cone is greatly enlarged.

FIG. 11C shows the radiation from the edge of a radiation-emitting semiconductor chip 10 with a flat radiation outcoupling surface 10a.

FIG. 11D shows that by introducing a curved radiation outcoupling surface 10a, the emission that occurs from the edge of the active region 3 does not benefit as much from the improved extraction cone as the emission from the center of the semiconductor chip 10.

FIG. 11E shows emission from a radiation-emitting semiconductor chip 10 with a flat radiation outcoupling surface 10a and a flat active region 3.

FIG. 11F shows that due to the curvature of the active region the problem of emission from the edge of the active region 3 is solved. At the same time, the curved radiation outcoupling surface 10a results in an improved extraction cone with an increased aperture angle.

The invention is not limited by the description given with reference to the embodiments. Rather, the invention encompasses any novel feature as well as any combination of features, which in particular includes any combination of features in the claims, even if this feature or this combination is not itself explicitly indicated in the claims or embodiments.

1.-13. (canceled)

14. A radiation-emitting semiconductor chip comprising:
a first doped region;
an active region adjacent to the first doped region, the active region configured to generate electromagnetic radiation; and
a second doped region arranged on a side of the active region facing away from the first doped region,
wherein the first doped region is structured in a step-like manner and comprises several planes in a direction perpendicular to a main extension plane of the radiation-emitting semiconductor chip, and
wherein the active region covers the first doped region on a side surface and a top surface.

15. The radiation-emitting semiconductor chip according to claim 14, wherein the active region completely covers the side surface of the first doped region.

16. The radiation-emitting semiconductor chip according to claim 14, wherein the first doped region is arranged on a substrate, and wherein the substrate comprises a flat top surface on the side facing the first doped region.

17. The radiation-emitting semiconductor chip according to claim 14, wherein the first doped region comprises a three-dimensional shape, and wherein the shape of the first doped region is approximated to a shape of a step pyramid.

18. The radiation-emitting semiconductor chip according to claim 14, wherein the radiation-emitting semiconductor chip comprises the main extension plane, wherein the active region extends obliquely to the main extension plane in places.

19. The radiation-emitting semiconductor chip according to claim 14, wherein the active region is curved.

20. The radiation-emitting semiconductor chip according to claim 14, wherein the first doped region tapers along the direction perpendicular to the main extension plane of the radiation-emitting semiconductor chip.

21. The radiation-emitting semiconductor chip according to claim 14, further comprising a first contact electrically conductively connected to the first doped region, wherein the first contact extends into the first doped region.

22. The radiation-emitting semiconductor chip according to claim 14, wherein the radiation-emitting semiconductor chip comprises an edge length less than or equal to 20 m.

23. The radiation-emitting semiconductor chip according to claim 14, further comprising a non-planar radiation outcoupling surface, wherein the active region is non-planar.

24. A method for manufacturing a radiation-emitting semiconductor chip, the method comprising:
providing a substrate;
depositing a first doped region;
structuring the first doped region such that the first doped region is structured in a step-like manner and tapers along a direction away from the substrate and comprises several planes;
depositing an active region such that the active region covers a side surface of the first doped region; and
depositing a second doped region on the active region.

25. The method according to claim 24, wherein structuring comprises multiple etching.

26. The method according to claim 24, wherein a part of the active region is deposited prior to a first deposition of the first doped region and the second doped region.

27. The method according to claim 26, wherein the active region is removed partially prior to a deposition of the first doped region and the second doped region taking place.

28. A radiation-emitting semiconductor chip comprising:
a first doped region;
an active region adjacent to the first doped region, the active region configured to generate electromagnetic radiation; and
a second doped region arranged on a side of the active region facing away from the first doped region,
wherein the first doped region is structured in a step-like manner and comprises several planes in a direction perpendicular to a main extension plane of the radiation-emitting semiconductor chip,
wherein the active region covers the first doped region on a side surface and a top surface, and
wherein the first doped region comprises a three-dimensional shape, the shape of the first doped region being approximated to a shape of a step pyramid.
